(19) United States
(12) Patent Application Publication
(10) Pub. No.: US 2025/0248020 A1
(43) Pub. Date: Jul. 31, 2025

(54) SEMICONDUCTOR DEVICE HAVING TRENCH CAPACITORS FORMED ON CHANNEL STRUCTURES AND METHODS FOR FABRICATING THE SAME

(71) Applicant: NANYA TECHNOLOGY CORPORATION, NEW TAIPEI CITY (TW)

(72) Inventor: PING HSU, NEW TAIPEI CITY (TW)

(21) Appl. No.: 18/585,496

(22) Filed: Feb. 23, 2024

Related U.S. Application Data
(62) Division of application No. 18/428,127, filed on Jan. 31, 2024.

(51) Int. Cl. H10B 12/00

(52) U.S. Cl. CPC H10B 12/033; H10B 12/05; H10B 12/315

(57) ABSTRACT

The present application discloses a semiconductor device and a method for fabricating the same. The semiconductor device includes a substrate, a first bit line disposed on the substrate and extending along a first direction, a first word line disposed on the first bit line and extending along a second direction perpendicular to the first direction, a channel structure disposed on the first bit line and penetrating the first word line, and a trench capacitor disposed on the channel structure. The channel structure is separated from the first word line by a gate dielectric layer.

### CROSS-REFERENCE TO RELATED APPLICATION

This application is a divisional application of U.S. Non-Provisional application Ser. No. 18/428,127 filed Jan. 31, 2024, which is incorporated herein by reference in its entirety.

### TECHNICAL FIELD

The present disclosure relates to a semiconductor device and a method of fabricating the same, and more particularly, to a semiconductor device having a trench capacitor formed on a channel structure.

### DISCUSSION OF THE BACKGROUND

An oxide semiconductor random-access memory (OSRAM) device is a type of random-access memory that stores each bit of data in a separate capacitor within an integrated circuit. Typically, an OSRAM is arranged in an array of one capacitor and one transistor per cell. In the current architecture of OSRAM, the capacitors are manufactured first. However, recently, OSRAM manufacturers have faced increasing challenges in improving both performance and yield in the manufacture of memory cells. For example, a channel of a bit line may be prone to contact a word line, which may induce a short circuit due to overlay errors in the lithography process.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a substrate; a first bit line disposed on the substrate and extending along a first direction; a first word line disposed on the first bit line and extending along a second direction perpendicular to the first direction; a channel structure disposed on the first bit line and penetrating the first word line; a first dielectric layer disposed over the first bit line and a second dielectric layer disposed over the first word line; and a trench capacitor disposed on the channel structure. The channel structure is separated from the first word line by a gate dielectric layer. The second dielectric layer comprises a first air gap structure.

Another aspect of the present disclosure provides a semiconductor device. The semiconductor device includes a substrate; a channel structure disposed on the substrate; a first word line disposed on the substrate and surrounding the channel structure; a dielectric layer disposed over the substrate; and a trench capacitor disposed on the channel structure, opposite to the substrate. The trench capacitor comprises a first conductive layer, a second conductive layer, a first dielectric layer and a second dielectric layer.

Another aspect of the present disclosure provides a method for fabricating a semiconductor device. The method includes providing a substrate; forming a first bit line on the substrate, wherein the first bit line extends along a first direction; forming a first word line above the first bit line, wherein the first word line extends along a second direction perpendicular to the first direction; forming a channel structure on the first bit line, wherein the channel structure penetrates the first word line; forming a dielectric layer over the substrate; and forming a trench capacitor on the channel structure.

The embodiments of the present disclosure provide a semiconductor device with a capacitor formed last, thereby differentiating process and structure of the semiconductor device from those of current practice. For example, in the current practice, a contact connecting a memory array to other elements is manufactured by stacking several contacts and stages, while the present disclosure provides a monolithic contact connecting to the memory array, whereby misaligned (failed) contacts may be avoided. Furthermore, as a word line of the present disclosure is positioned near lower conductive layers on a substrate, resistance of connections may be reduced due to reduced length of electrical path of the shorter word line contact.

Regarding potential failure of a channel structure, an etching process for fabricating the channel structure may be incapable of creating a channel of sufficient depth; in such cases, a bottom surface of the channel structure may contact the word line, such that the channel structure and the word line are short-circuited. In current practice, since a bit line is disposed on a channel structure, a short circuit may occur between the bit line and the word line through the failed channel structure, and thus other channel structures connected to the same bit line will fail as well. In contrast, the present disclosure provides a semiconductor device with a capacitor formed last (i.e., the capacitor is disposed on a channel structure). With such configuration, a short circuit may occur between a word line and the capacitor (instead of a bit line) through a failed channel structure, and thus only one memory cell (containing the failed channel structure) is impacted. Accordingly, yield and performance of the semiconductor device may be improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It may also be appreciated by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1A is a cross-sectional view of a semiconductor device in accordance with some embodiments of the present disclosure.

FIG. 1B is an enlarged perspective view of a region A in FIG. 1A.

FIG. 1C is a top view of a semiconductor structure along a line B-B of FIG. 1B.

FIG. 1D is an enlarged perspective view of the region A in FIG. 1A, in accordance with alternative embodiments of the present disclosure.

FIG. 1E is an enlarged perspective view of a region B in FIG. 1A, in accordance with alternative embodiments of the present disclosure.

FIG. 2A is a cross-sectional view of a semiconductor device in accordance with some embodiments of the present disclosure.

FIG. 2B is an enlarged perspective view of a region C in FIG. 2A.

FIGS. 3A, 3B, 3C, 3D, 3E, 3F, 3G and 3H illustrate one or more operations of a method for fabricating a semiconductor device in accordance with some embodiments of the present disclosure.

FIG. 4 is a flowchart of a method for fabricating a semiconductor device in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

It should be noted that the term “about” modifying the quantity of an ingredient, component, or reactant of the present disclosure refers to variation in the numerical quantity that may occur, for example, through typical measuring and liquid handling procedures used for making concentrates or solutions. Furthermore, variation may occur from inadvertent error in measuring procedures, differences in the manufacture, source, or purity of the ingredients employed to make the compositions or to carry out the methods, and the like. In one aspect, the term “about” means within 10% of the reported numerical value. In another aspect, the term “about” means within 5% of the reported numerical value. In yet another aspect, the term “about” means within 10%, 9%, 8%, 7%, 6%, 5%, 4%, 3%, 2% or 1% of the reported numerical value.

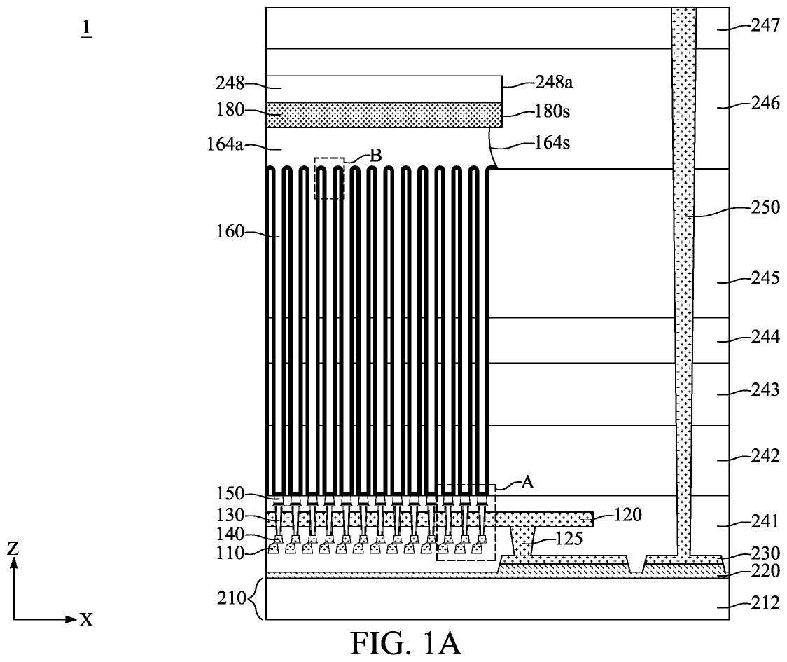

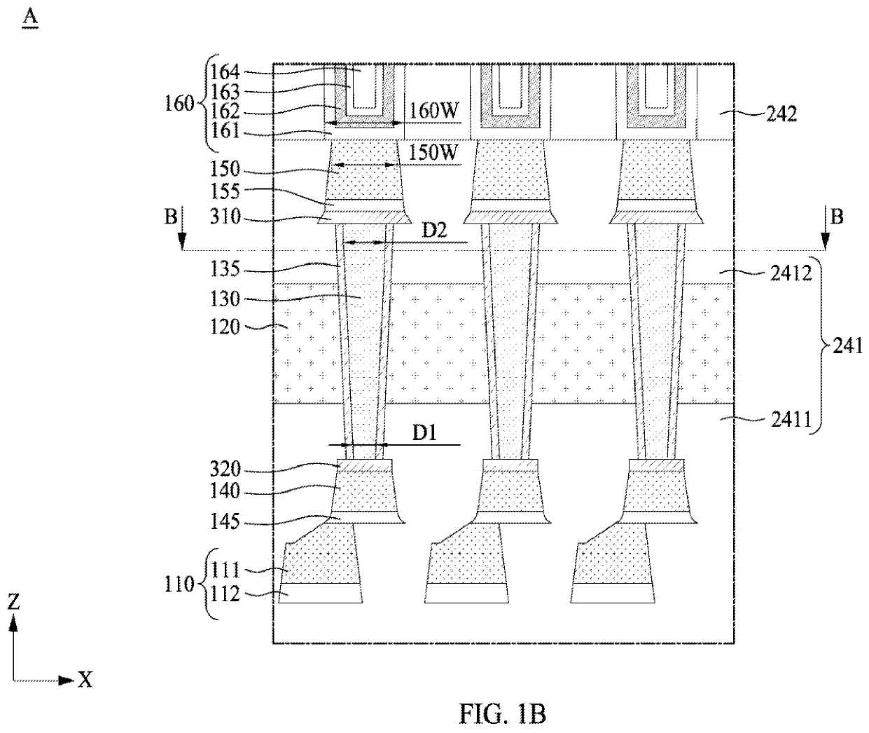

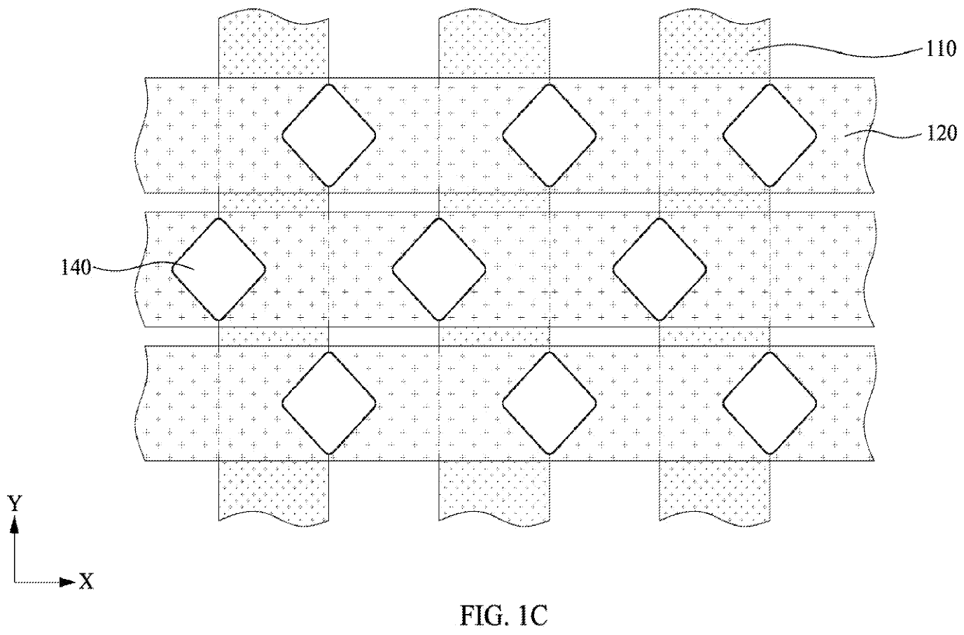

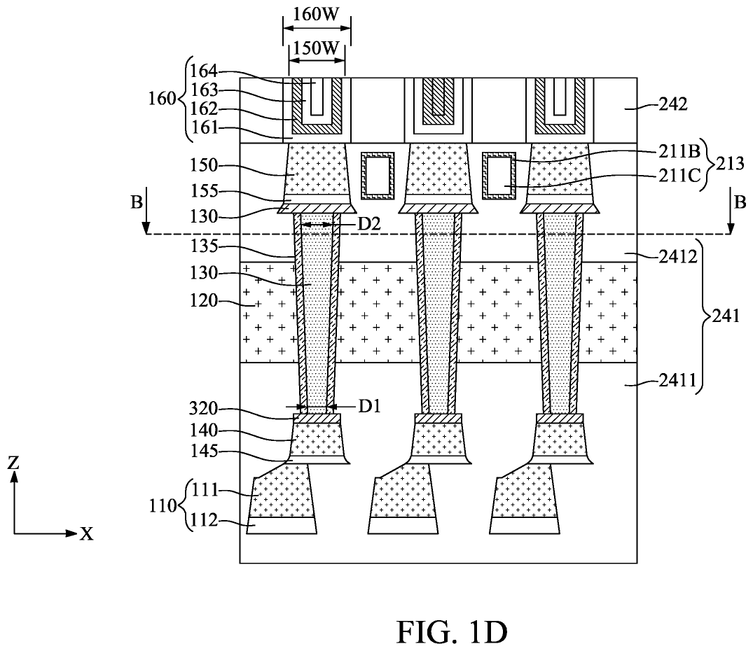

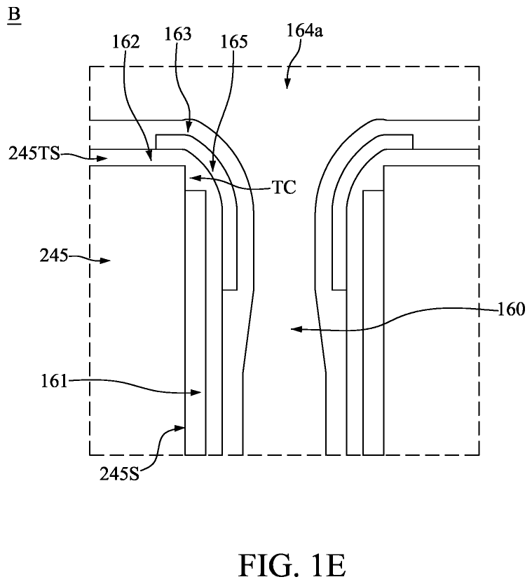

FIG. 1A is a cross-sectional view of a semiconductor device 1 in accordance with some embodiments of the present disclosure.

The semiconductor device 1 may include a memory, a memory device, a memory die, a memory chip, or other components. The semiconductor device 1 may be a portion of the memory, the memory device, the memory die, or the memory chip. For example, the memory may be a dynamic random-access memory (DRAM). In some embodiments, the DRAM may be a double-data-rate fourth-generation (DDR4) DRAM. In some embodiments, the memory may be an oxide semiconductor random-access memory (OSRAM). In some embodiments, the memory includes one or more memory cells, memory bits, or memory blocks.

The semiconductor device 1 includes a substrate 210, conductive layers 220 and 230, dielectric layers 241, 242, 243, 244, 245, 246 and 247, bit lines 110, a word line 120, a word line contact 125, channel structures 130, lower landing pads 140, upper landing pads 150, trench capacitors 160, a contact layer 164a, a conductive layer 180, a dielectric layer 248, and a contact 250.

Referring to FIG. 1A, the substrate 210 may be a semiconductor substrate, such as a bulk semiconductor, a semiconductor-on-insulator (SOI) substrate, or the like. The substrate 210 may include an elementary semiconductor including silicon or germanium in a single crystal form, a polycrystalline form or an amorphous form; a compound semiconductor material including at least one of silicon carbide, gallium arsenide, gallium phosphide, indium phosphide, indium arsenide and indium antimonide; an alloy semiconductor material including at least one of SiGe, GaAsP, AlInAs, AlGaAs, GaInAs, GaInP and GaInAsP; any other appropriate materials; or a combination thereof. In some embodiments, the alloy semiconductor substrate may be a SiGe alloy with a gradient SiGe feature in which the Si/Ge composition changes from one ratio at one location to another ratio at another location of the gradient SiGe feature. In another embodiment, the SiGe alloy is formed over a silicon substrate. In some embodiments, a SiGe alloy may be mechanically strained by another material in contact with the SiGe alloy. In some embodiments, the substrate 210 may be multilayered, or the substrate 210 may include a multilayered compound semiconductor structure.

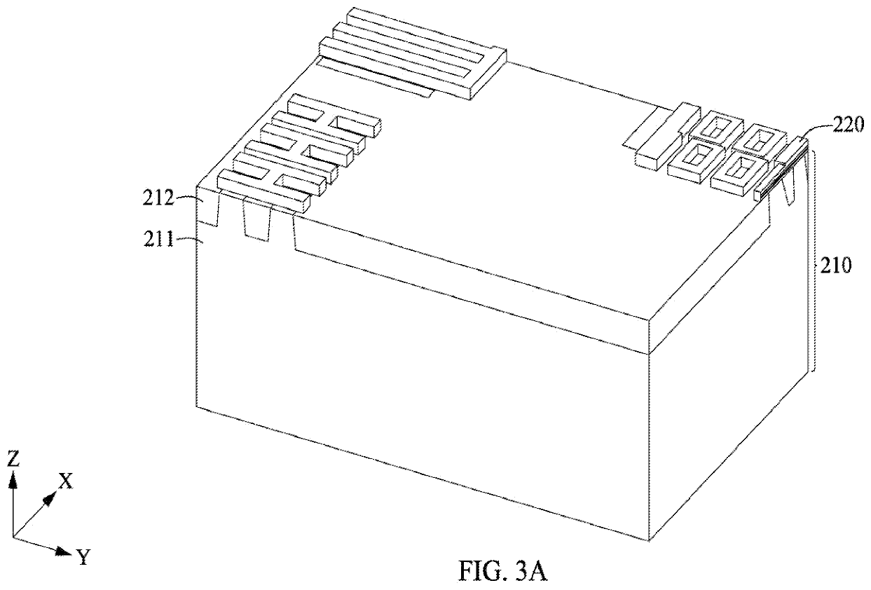

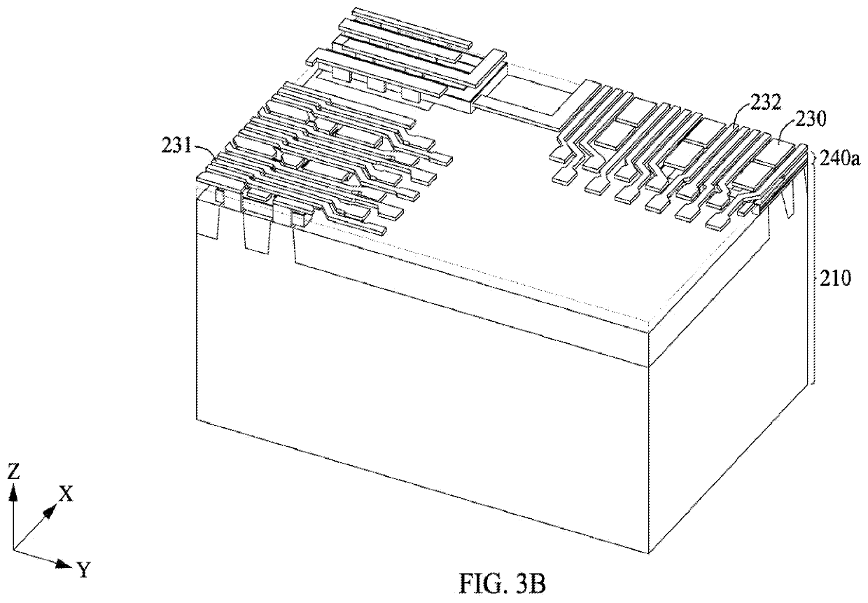

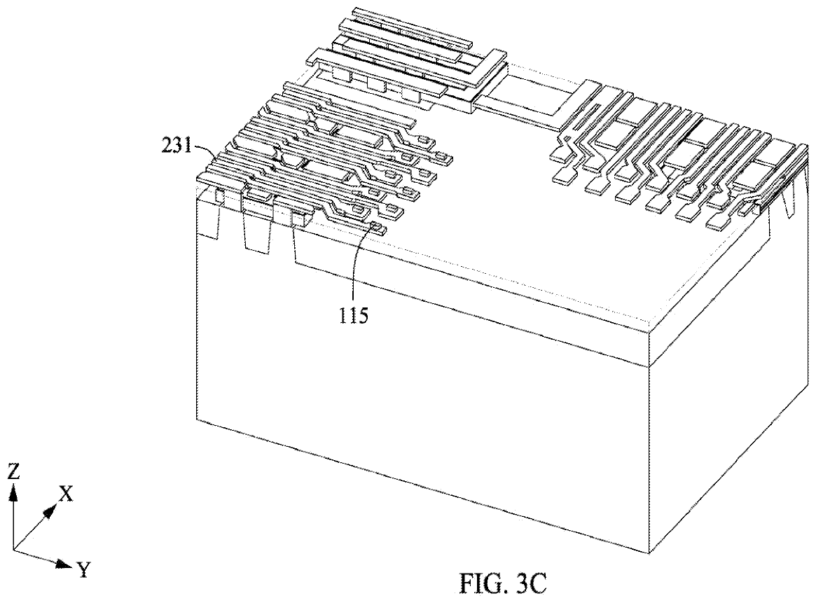

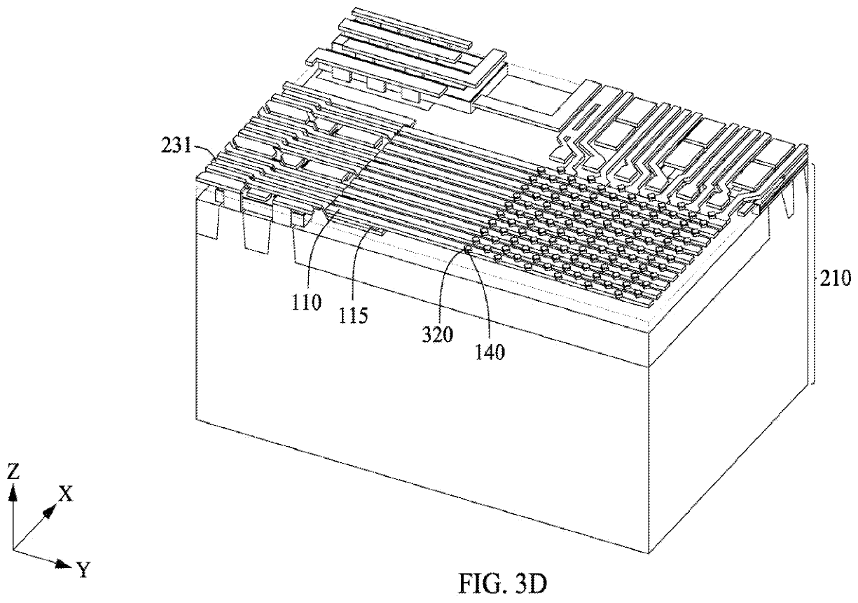

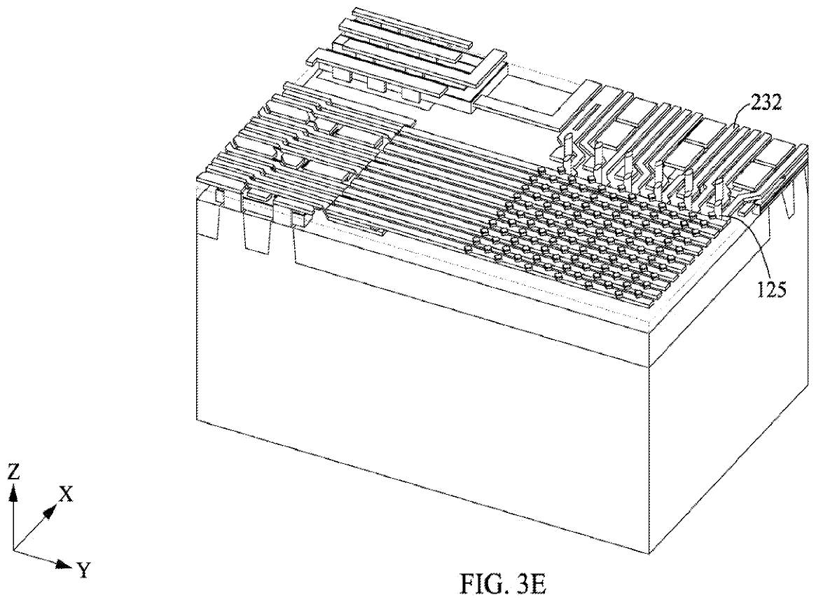

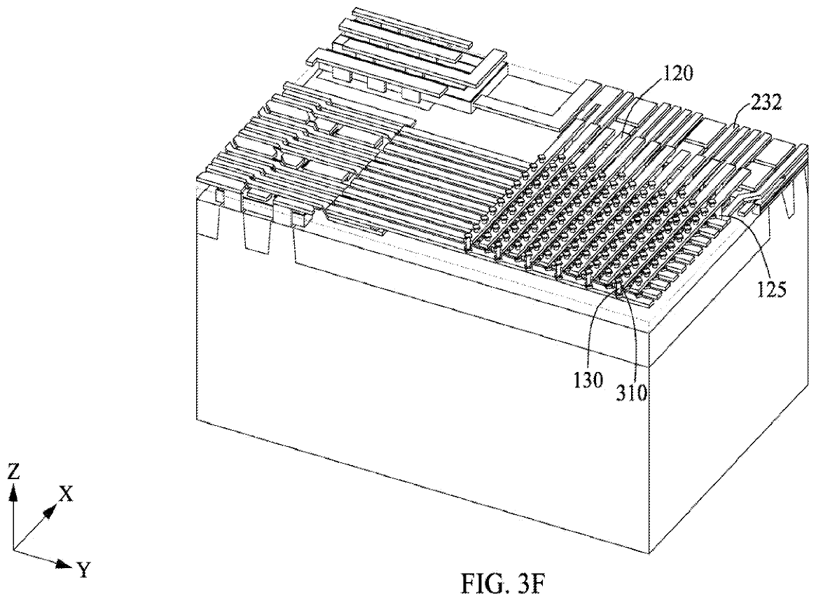

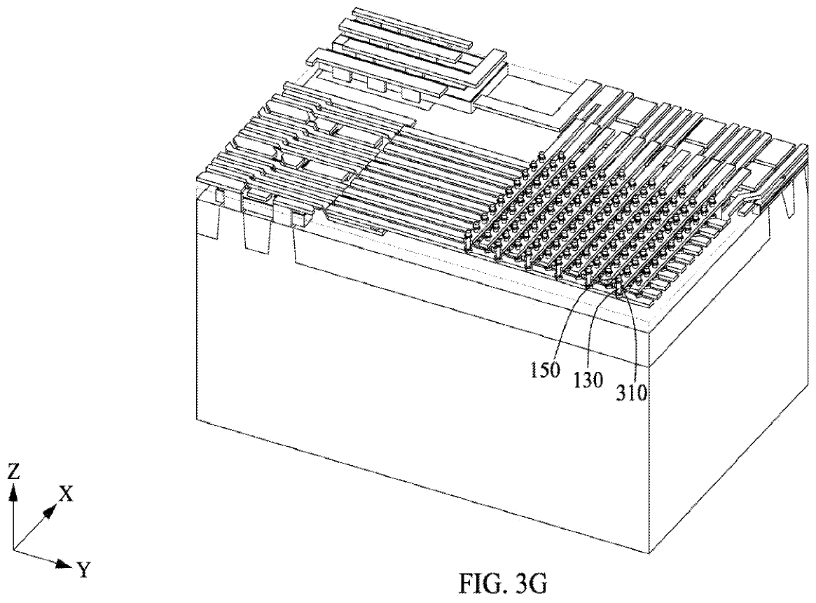

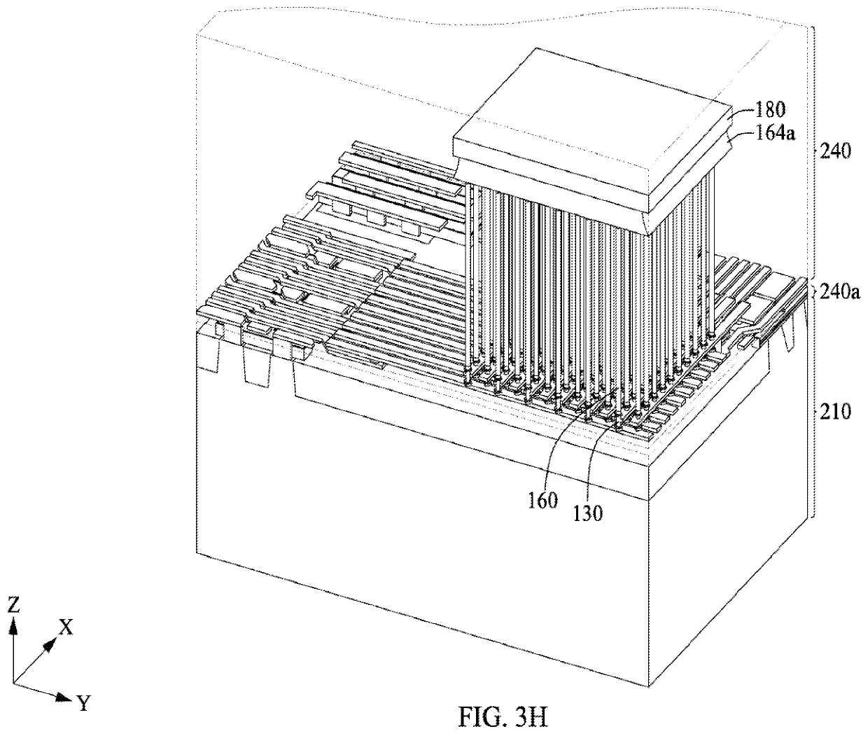

In some embodiments, the substrate 210 may include an isolation structure 212 and a plurality of active areas (not shown). A relationship between the isolation structure 212 and the substrate 210 is illustrated in detail in FIG. 3A. In some embodiments, the isolation in structure 212 may include, for example, silicon oxide (SiO₂), silicon nitride (Si₃N₄), silicon oxynitride (N₂OSi₂), silicon nitride oxide (N₂OSi₂), or other appropriate materials. The active area may function as, for example, a channel for electrical connection. In some embodiments, the plurality of active areas may be separated by the isolation structures 212.

The conductive layer 220 may be disposed on the substrate 210. In some embodiments, the conductive layer 220 may be disposed on the isolation structure 212 of the substrate 210. In some embodiments, the conductive layer 220 may be electrically connected to the active areas of the substrate 210 (not shown). The conductive layer 220 may be patterned. That is, the conductive layer 220 may expose a part of the substrate 210 (not shown in FIG. 1A).

The conductive layer 220 may include metal, such as W, Cu, Ru, Ir, Ni, Os, Rh, Al, Mo, Co, alloys thereof, combinations thereof or any metallic material with appropriate resistance and gap-filling capability.

In some embodiments, the conductive layer 230 may be formed on the conductive layer 220. In some embodiments, the conductive layer 230 may be electrically connected to the active areas of the substrate 210 through the conductive layer 220 (not shown). The conductive layer 230 may be a patterned layer corresponding to a pattern of the conductive layer 220.

The conductive layer 230 may be formed of a material similar or identical to the material of the conductive layer 220. For example, the conductive layer 220 may include copper (Cu), and the conductive layer 230 may include tungsten (W).

The semiconductor device 1 may include an array of transistors (for example, as shown in a region A) disposed on the substrate 210. The array of transistors may include the bit lines 110, the lower landing pads 140, the channel structures 130, the word line 120, and the upper landing pads 150.

Details of the array of transistors are provided below with reference to FIGS. 1A, 1B and 1C. FIG. 1B is an enlarged perspective view of the region A in FIG. 1A. FIG. 1C is a top view of the semiconductor structure 1 along a line B-B of FIG. 1B, wherein the channel structure 130 and a gate dielectric layer 135 are omitted for clarity.

The semiconductor device 1 may include a plurality of bit lines 110 disposed on the substrate 210. The bit lines 110 may extend along the Y-axis, which is perpendicular to the X-axis and the Z-axis. The bit lines 110 may extend in parallel. In some embodiments, a number of the bit lines 110 may be 1, 2, 3, 4, 5, 6, 7, 8, 9, 10, 11, 12, 13 or more. The bit lines 110 may be electrically connected to the active areas of the substrate 210 (not shown).

The bit lines 110 may include conductive materials, such as tungsten, copper, aluminum, tantalum, tantalum nitride, titanium, titanium nitride, the like, and/or a combination thereof. Referring to FIG. 1B, for example, the bit lines 110 may include a titanium nitride layer 112 and a tungsten layer 111 disposed on the titanium nitride layer 112 opposite to the substrate 210. In some embodiments, the titanium nitride layer 112 may have a minimal thickness. For example, the thickness of the titanium nitride layer 112 may be less than that of the tungsten layer 111.

In some embodiments, the bit lines 110 may taper toward the channel structures 130. That is, the bit lines 110 may have an upper width less than a lower width thereof. For example, a width of the titanium nitride layer 112 may be greater than a width of the tungsten layer 111.

During manufacture, either the titanium nitride layer 112 or the tungsten layer 111 may be formed by a removal operation. In some embodiments, the removal operation may be an etching process, such as an anisotropic etching process or an isotropic etching process.

Referring to FIG. 1B, the lower landing pads (LP) 140 are disposed on the bit lines 110. Each of the lower landing pads 140 may correspond to a respective one of the bit lines 110. In some embodiments, each of the lower landing pads 140 may partially cover the respective one of the bit lines 110. That is, a projection of the lower landing pad 140 on the substrate 210 may partially overlap a projection of the corresponding bit line 110 on the substrate 210.

FIG. 1C is a top view of the semiconductor structure along the line B-B of FIG. 1B. Referring to FIG. 1C, the lower landing pads 140 may form a quadrilateral in the top view. In some embodiments, the lower landing pads 140 may form a parallelogram. For example, the lower landing pads 140 may be a rhombus. The lower landing pads 140 may be partially disposed on the bit lines 110, which extend along the Y-axis. For example, one-half of each of the lower landing pads 140 may overlap one of the bit lines 110.

The lower landing pads 140 may include metal, such as W, Cu, Ru, Ir, Ni, Os, Rh, Al, Mo, Co, alloys thereof, combinations thereof or any metallic material with appropriate resistance and gap-filling capability. Preferably, the lower landing pads 140 may be made of tungsten (W) or an alloy thereof.

Referring back to FIG. 1B, the lower landing pads 140 may contact the bit lines 110 through a titanium nitride layer 145. In some embodiments, each of the lower landing pads 140 may have the titanium nitride layer 145. In some embodiments, the titanium nitride layer 145 may have a minimal thickness. For example, the thickness of the titanium nitride layer 145 may be less than a thickness of the lower landing pad 140.

In some embodiments, the lower landing pads 140 may taper toward the channel structures 130. That is, the lower landing pads 140 may have an upper width less than a lower width. For example, a width of the titanium nitride layer 145 may be greater than a width of the lower landing pad 140.

During manufacture, either the titanium nitride layer 145 or the lower landing pads 140 may be formed by a removal operation. In some embodiments, the removal operation of the lower landing pads 140 may be partially conducted on the bit lines 110. A portion of the bit lines 110 may be removed, such that a lateral surface of the lower landing pad 140 may smoothly connect to a top surface of the bit line 110. In some embodiments, the bit lines 110 having such structure may be separated by a greater distance from an adjacent lower landing pad 140 (for example, the left) to avoid short circuiting therebetween.

Referring to FIG. 1B, an indium tin oxide (ITO) layer 320 may be disposed on the lower landing pads 140. In some embodiments, the ITO layer 320 may be disposed between the channel structures 130 and the lower landing pads 140. In some embodiments, the ITO layer 320 may have a minimal thickness. For example, the thickness of the ITO layer 320 may be less than that of the lower landing pads 140.

A dielectric layer 2411 may be disposed on the substrate 210 and cover the bit lines 110, the lower landing pads 140, and the ITO layer 320. In other words, the bit lines 110, the lower landing pads 140, and the ITO layer 320 may be surrounded by the dielectric layer 2411.

In some embodiments, the dielectric layer 2411 may include silicon oxide (SiOₓ), silicon nitride (SiₓN_{y}), silicon oxynitride (SiON), phosphosilicate glass (PSG), borophosphosilicate glass (BPSG), a low-k dielectric material (k<4), or other appropriate materials.

The channel structures 130 may be disposed on the lower landing pads 140 through the ITO layer 320. In some embodiments, the channel structure 130 may be disposed on the bit lines 110 and electrically connected to the bit lines 110. In some embodiments, the channel structures 130 may penetrate the word line 120. Each of the channel structures 130 may correspond to a respective one of the lower landing pads 140. In some embodiments, each of the channel structures 130 may align with the respective one of the lower landing pads 140. That is, a projection of the channel structure 130 on the substrate 210 may overlap a projection of the corresponding lower landing pad 140 on the substrate 210.

Each of the channel structures 130 may correspond to a respective one of the bit lines 110. In some embodiments, each of the channel structures 130 may partially cover the corresponding bit line 110. That is, the projection of the channel structure 130 on the substrate 210 may partially overlap a projection of the bit line 110 on the substrate 210.

In some embodiments, the channel structure 130 may taper toward the bit line 110. That is, the channel structure 130 tapers along the Z-axis away from the trench capacitor 160. The channel structure 130 may have an upper diameter D2 adjacent to the upper landing pads 150 greater than a lower diameter D1 adjacent to the lower landing pads 140. For example, the channel structure 130 may have an upper width (D2) greater than a lower width (D1).

A material of the channel structures 130 may include an amorphous semiconductor, a poly-semiconductor and/or metal oxide. The semiconductor may include, but is not limited to, germanium (Ge), silicon (Si), tin (Sn), and antimony (Sb). The metal oxide may include, but is not limited to, indium oxide; tin oxide; zinc oxide; a two-component metal oxide such as an InZn-based oxide, a SnZn-based oxide, an AlZn-based oxide, a ZnMg-based oxide, a SnMg-based oxide, an InMg-based oxide, or an InGa-based oxide; a three-component metal oxide such as an InGaZn-based oxide (also represented as IGZO), an InAlZn-based oxide, an InSnZn-based oxide, a SnGaZn-based oxide, an AlGaZn-based oxide, a SnAlZn-based oxide, an InHfZn-based oxide, an InLaZn-based oxide, an InCeZn-based oxide, an InPrZn-based oxide, an InNdZn-based oxide, an InSmZn-based oxide, an InEuZn-based oxide, an InGdZn-based oxide, an InTbZn-based oxide, an InDyZn-based oxide, an InHoZn-based oxide, an InErZn-based oxide, an InTmZn-based oxide, an InYbZn-based oxide, or an InLuZn-based oxide; and a four-component metal oxide such as an InSnGaZn-based oxide, an InHfGaZn-based oxide, an InAlGaZn-based oxide, an InSnAlZn-based oxide, an InSnHfZn-based oxide, or an InHfAlZn-based oxide, but the present disclosure is not limited in this regard.

Referring to FIG. 1B, the gate dielectric layer 135 may surround the channel structure 130. The gate dielectric layer 135 may be formed between the channel structure 130 and the word line 120. In some embodiments, the channel structure 130 may be separated from the word line 120 by the gate dielectric layer 135.

In some embodiments, the gate dielectric layer 135 may include silicon oxide (SiOₓ), silicon nitride (SiₓN_{y}), silicon oxynitride (SiON), or a combination thereof. In some embodiments, the gate dielectric layer 135 may include a dielectric material, such as a high-k dielectric material. The high-k dielectric material may have a dielectric constant (k value) greater than 4. The high-k dielectric material may include hafnium oxide (HfO₂), zirconium oxide (ZrO₂), lanthanum oxide (La₂O₃), yttrium oxide (Y₂O₃), aluminum oxide (Al₂O₃), titanium oxide (TiO₂) or another applicable material. Other appropriate materials are within the contemplated scope of this disclosure.

The word line 120 may be disposed on the dielectric layer 2411. The word line 120 may extend along the X-axis. Referring to FIG. 1C, the word line 120 may extend in a direction perpendicular to the direction (Y-axis) of the bit lines 110. The word line 120 may overlap the lower landing pad 140. That is, the word line 120 may overlap the channel structure 130 (not shown in FIG. 1C), which is aligned with the lower landing pad 140.

Referring to FIG. 1C, from a top view perspective, the word lines 120 and the bit lines 110 are orthogonal. Each of the lower landing pads 140 may overlap the corresponding word line 120 and may partially overlap the corresponding bit line 110. The lower landing pad 140 may include, but is not limited to, a quadrilateral shape. In some embodiments, the lower landing pad 140 may further include triangle, pentagon or hexagon shapes.

Referring to FIG. 1B, the word line 120 may surround the channel structures 130. The word line 120 may cover a lateral surface of the channel structures 130. The word line 120 may contact the gate dielectric layer 135. In some embodiments, the semiconductor device 1 may include one or more word lines 120.

In some embodiments, an etching process for fabricating the channel structure 130 may fail to create a channel of sufficient depth. In such case, a bottom surface of the channel structure 130 may contact the word line 120, such that the channel structure 130 and the word line 120 are short-circuited. In comparative embodiments, because a bit line is disposed on a channel structure, a short circuit may occur between the bit line and a word line through a failed channel structure, and thus other channel structures connected to the same bit line will fail as well. In contrast, the present disclosure provides the semiconductor device with a capacitor formed last (i.e., the capacitor is disposed on the channel structure). With such configuration, a short circuit may occur between the word line 120 and the capacitor 160 through the failed channel structure, and thus only one memory cell (containing the failed channel structure) is affected. Accordingly, manufacturing yield of the semiconductor device may be improved.

Referring to FIG. 1A, the word line 120 may extend outside of the array of the transistors. In some embodiments, the semiconductor device 1 may include the word line contact 125 disposed between the word line 120 and the conductive layer 230. The word line contact 125 may penetrate the dielectric layer 2411 and connect the word line 120 to the conductive layer 230. The word line contact 125 may be spaced apart from the channel structures 130.

The word line contact 125 may include metal, such as W, Cu, Ru, Ir, Ni, Os, Rh, Al, Mo, Co, alloys thereof, combinations thereof, or any metallic material with appropriate resistance and gap-filling capability.

Referring to FIG. 1B, the upper landing pads 150 are disposed on the channel structures 130. Each of the upper landing pads 150 may correspond to a respective one of the channel structures 130. In some embodiments, each the upper landing pads 150 may align with the corresponding channel structure 130. That is, a projection of the upper landing pad 150 on the substrate 210 may overlap the projection of the channel structure 130 on the substrate 210.

In some embodiments, each of the upper landing pads 150 may align with a corresponding one of the lower landing pads 140. In other words, the upper landing pads 150 may cover the lower landing pads 140. In some embodiments, the upper landing pads 150 may have a shape and/or material similar to those of the lower landing pads 140.

In some embodiments, the upper landing pads 150 may be formed of a material similar to that of the lower landing pads 140.

In some embodiments, the upper landing pads 150 may be connected to the channel structures 130 through a titanium nitride layer 155. Each of the upper landing pads 150 may have a titanium nitride layer 155. In some embodiments, the titanium nitride layer 155 may be similar to the titanium nitride layer 145.

In some embodiments, the upper landing pads 150 may taper away from the channel structures 130. The upper landing pads 150 may taper toward the trench capacitors 160. That is, the upper landing pads 150 may have an upper width 150W less than a lower width. For example, a width of the titanium nitride layer 155 may be greater than a width of the upper landing pads 150.

During manufacture, either the titanium nitride layer 155 or the upper landing pads 150 may be formed by a removal operation. In some embodiments, the removal operation may be an etching process, such as an anisotropic etching process or an isotropic etching process.

Referring to FIG. 1B, an indium tin oxide (ITO) layer 310 may be disposed on the channel structures 130. In some embodiments, the ITO layer 310 may be disposed between the channel structures 130 and the upper landing pads 150. In some embodiments, the ITO layer 310 may be similar to the ITO layer 320.

In some embodiments, the ITO layers 310 and 320 may be a source/drain structure. The channel structures 130 may connect the ITO layer 310 to the ITO layer 320, and the channel structures 130 may be configured to turn on and off in response to a signal (for example, a voltage or a current) transmitted from the word line 120 through the gate dielectric layer 135.

A dielectric layer 2412 may be disposed on the word line 120 and may cover the upper landing pads 150, the ITO layer 310, and the channel structures 130. In other words, the upper landing pads 150, the ITO layer 310, and the channel structures 130 may be surrounded by the dielectric layer 2412. In some embodiments, the channel structure 130 may penetrate the dielectric layers 2411 and 2412 and the word line 120. In some embodiments, the dielectric layer 2412 may be identical to or similar to the dielectric layer 2411. In some embodiments, as shown in FIG. 1D, the dielectric layer 2412 includes an air gap structure 213 disposed between a pair of the upper landing pads 150. The air gap structure 213 has an air gap 211C enclosed by a liner 211B as shown in FIG. 1D. In some embodiments, the air gap structure 213 may be formed by deposing an energy removable block within the dielectric layer 2412, wherein the energy removable block is made of an energy removable material. Next, a thermal treatment process may be performed to transform the energy removable block into the air gap structure 213 including the air gap 211C enclosed by the liner 211B.

The dielectric layers 2411 and 2412 may be formed in different fabricating steps. The dielectric layers 2411 and 2412 may form the dielectric layer 241 (as shown in FIG. 1A). That is, the dielectric layer 241 may surround the array of transistors and the word line contact 125.

Referring to FIG. 1A, the dielectric layers 242, 243, 244 and 245 may be disposed on the dielectric layer 241. The dielectric layers 242, 243, 244 and 245 may be disposed on the array of transistors. The dielectric layers 242, 243, 244 and 245 may be formed in different fabricating steps or in one step. In some embodiments, the dielectric layers 242, 243, 244 and 245 may be formed of a same material or of similar materials. In another embodiment, the dielectric layers 242, 243, 244 and 245 may be formed of a same material at different concentrations. The dielectric layers 242, 243, 244 and 245 may be formed of a material similar to that of the dielectric layer 241.

The trench capacitors 160 may be disposed on the channel structures 130. In some embodiments, the trench capacitors 160 may penetrate the dielectric layers 242, 243, 244 and 245 and connect to the channel structures 130. The trench capacitors 160 may taper toward the channel structures 130. In some embodiments, the trench capacitors 160 may be electrically connected to the channel structures 130 through the upper landing pads 150 and the ITO layer 310. In some embodiments, the upper width 150W of the upper landing pads 150 may be equal to or less than a lower width 160W of the trench capacitors 160 adjacent to the upper landing pads 150.

Each of the trench capacitors 160 may correspond to a respective one of the channel structures 130 of the array of transistors. That is, the trench capacitors 160 are arranged in an array. In some embodiments, each of the trench capacitors 160 may be referred to as a capacitor cell.

Referring to FIG. 1B, the trench capacitors 160 may include a multilayered stack (including conductive layers 161 and 163 and a dielectric layer 162) and a contact material 164. During manufacture of the trench capacitors 160, portions of the dielectric layers 242, 243, 244 and 245 may be removed to form a plurality of trenches. The multilayered stack may be formed within the trenches, and the contact material 164 may then be deposited in the trench.

The conductive layer 161 may be disposed on the dielectric layer 245 (see FIG. 1A). The conductive layer 161 may be disposed within the trenches. The conductive layer 161 may cover lateral surfaces of the dielectric layers 242, 243, 244 and 245. A portion of the conductive layer 161 may be disposed on the upper landing pads 150. The conductive layer 161 may have an underside coplanar with a top surface of the upper landing pads 150. In some embodiments, the conductive layer 161 may contact the upper landing pads 150.

The dielectric layer 162 may be disposed on the conductive layer 161. In some embodiments, the dielectric layer 162 may be disposed on the dielectric layer 245 (see FIG. 1A). The dielectric layer 162 may be disposed within the trenches. The dielectric layer 162 may cover lateral surfaces of the dielectric layers 242, 243, 244 and 245. A portion of the dielectric layer 162 may be disposed on the upper landing pads 150. In some embodiments, an underside of the dielectric layer 162 may be coplanar with a top surface of the conductive layer 161.

In some embodiments, the conductive layer 163 may be disposed on the dielectric layer 162. The conductive layer 163 may be disposed on the dielectric layer 245 (see FIG. 1A). The conductive layer 163 may be disposed within the trenches. The conductive layer 163 may cover lateral surfaces of the dielectric layers 242, 243, 244 and 245. A portion of the conductive layer 163 may be disposed on the upper landing pads 150. In some embodiments, an underside of the conductive layer 163 may be coplanar with a top surface of the dielectric layer 162.

The multilayered stack of the trench capacitor 160 in FIG. 1B includes two conductive layers 161 and 163 and one dielectric layer 162. However, in alternative embodiments, the multilayered stack of the trench capacitor 160 may include more conductive layers and more dielectric layers. For example, the trench capacitor 160 may include two conductive layers 161 and 163 and two dielectric layers 162 and 165, in accordance with FIG. 1E. The multilayered stack of the trench capacitor 160 in FIG. 1B and that in the FIG. 1E are similar in many aspects, and thus descriptions of similar features will not be repeated herein. Main differences are described below.

Referring to FIGS. 1A and 1E, in alternative embodiments, the conductive layer 161 may be disposed within the trenches. The conductive layer 161 may cover lateral surfaces of the dielectric layers 242, 243 and 244 and may partially cover a lateral surface of the dielectric layer 245. The dielectric layer 162 may be disposed over the dielectric layer 245 and may cover the conductive layer 161 within the trenches. The dielectric layer 165 may be disposed over the dielectric layer 245 and disposed on the trench corner TC of the trenches and may partially cover a top surface and a lateral surface of the dielectric layer 245. The conductive layer 163 may be disposed over the dielectric layer 245 and the dielectric layer 165 and may cover lateral surfaces of the dielectric layers 242, 243, 244 and 245.

Referring to FIGS. 1B and 1E, in some embodiments, the conductive layers 161 and 163 and the dielectric layers 162 and 165 may have a same thickness. In another embodiment, thicknesses of the conductive layers 161 and 163 and the dielectric layers 162 and 165 may be different. The thickness of the conductive layer 161 may equal or exceed that of the dielectric layer 162. The thickness of the dielectric layer 162 may equal or exceed that of the conductive layer 163. The thickness of the conductive layer 163 may equal or exceed that of the dielectric layer 165.

Referring to FIGS. 1B and 1E, in some embodiments, the conductive layers 161 and 163 may be formed of a same material. For example, the material of the conductive layers 161 and 163 may include titanium nitride (TiN). In some embodiments, the dielectric layers 162 and 165 may be formed of a high-k dielectric material. For example, the dielectric layer 162 may include zirconium oxide (ZrO₂), titanium oxide (TiO₂), or a combination thereof.

Referring to FIGS. 1A, 1B and 1E, the contact material 164 of the trench capacitor 160 may be disposed on the multilayered stack (including conductive layers 161 and 163 and the dielectric layer 162 in FIG. 1B or including conductive layers 161 and 163 and the dielectric layers 162 and 165 in FIG. 1E). In some embodiments, the contact material 164 may be disposed within the trench defined by the multilayered stack. The contact material 164 may cover a lateral surface of the conductive layer 163. In some embodiments, the contact material 164 may be formed of a semiconductor material. For example, the contact material 164 may be formed of polysilicon. In some embodiments, the contact material 164 of the trench capacitor 160 may be configured to receive electrical voltage.

Referring to FIG. 1A, the contact material 164 may form a contact layer 164a disposed on the dielectric layer 245. The contact layer 164a may be disposed on the trench capacitors 160, opposite to the channel structures 130. In some embodiments, the contact layer 164a may include a sidewall 164s. The sidewall 164s may be non-planar. In some embodiments, the sidewall 164s may be curved.

In some embodiments, the conductive layer 180 may be disposed on the contact layer 164a. In some embodiments, an underside of the conductive layer 180 may be coplanar with a top surface of the contact layer 164a. The conductive layer 180 may have a width greater than that of the contact layer 164a. The conductive layer 180 may have a sidewall 180s. The sidewall 164s of the contact layer 164a may be recessed from the sidewall 180s of the conductive layer 180. In some embodiments, the conductive layer 180 and the contact material 164a may be configured to receive electrical voltage (not shown).

The conductive layer 180 may include metal, such as W, Cu, Ru, Ir, Ni, Os, Rh, Al, Mo, Co, alloys thereof, combinations thereof, or any metallic material with appropriate resistance and gap-filling capability.

The dielectric layer 248 may be disposed on the conductive layer 180. The dielectric layer 248 may have a width identical to that of the conductive layer 180. In some embodiments, the dielectric layer 248 may have a sidewall 248a. The sidewall 248s of the dielectric layer 248 may be coplanar with the sidewall 180s. In some embodiments, the dielectric layer 248 may be formed of a material similar to that of the dielectric layer 241.

In some embodiments, the contact layer 164a, the conductive layer 180, and the dielectric layer 248 may be referred to as a top cell plate (TCP). In some embodiments, after the contact layer 164a, the conductive layer 180, and the dielectric layer 248 are formed on the dielectric layer 245, a removal operation may be conducted on the contact layer 164a, the conductive layer 180, and the dielectric layer 248, such that a periphery region (i.e., a region apart from the trench capacitors 160, that is, the right side in FIG. 1A) of the contact layer 164a, the conductive layer 180, and the dielectric layer 248 may be removed.

The dielectric layer 246 may be disposed on the dielectric layer 245. The dielectric layer 246 may be disposed on the conductive layer 180. The dielectric layer 246 may cover the dielectric layer 248, the conductive layer 180 and the contact layer 164a. That is, the lateral surfaces of the dielectric layer 248, the conductive layer 180 and the contact layer 164a may be covered by the dielectric layer 246. In some embodiments, the dielectric layer 246 may be formed of a material similar to that of the dielectric layer 248 (i.e., similar to the dielectric layer 241).

The dielectric layer 247 may be disposed on the dielectric layer 246. In some embodiments, the dielectric layer 247 may be formed of a material similar to that of the dielectric layer 241. In some embodiments, the dielectric layers 241, 242, 243, 244, 245, 246, 247 and 248 may be formed of a same material at different concentrations.

Referring to FIG. 1A, the contact 250 may be disposed on and electrically connected to the conductive layer 230. In some embodiments, the contact 250 may penetrate the dielectric layers 241, 242, 243, 244, 245, 246 and 247. The contact 250 is spaced apart from the channel structures 130. In some embodiments, the contact 250 may be a monolithic structure.

The contact 250 may be electrically connected to the word line contact 125 through the conductive layers 220 and 230. The word line 120 is electrically connected to the contact 250 through the word line contact 125 and the conductive layers 220 and 230. The contact 250 may connect the conductive layer 230 to an upper conductive layer (not shown) for an electrical connection.

In the present disclosure, as the array of transistors (or word line) is disposed near lower conductive layers (for example, the conductive layers 220 and 230), a resistance of the connection may be reduced due to a shortened electrical path (i.e., due to a shorter word line contact 125).

In comparative embodiments, a contact connecting a memory array of a semiconductor device to other elements is manufactured by stacking several contacts and stages. A defect, referred to as a “missed contact,” may occur if one or more of the contacts and stages are misaligned during fabrication. The missed contact may jeopardize functions of the semiconductor device. On the other hand, the present disclosure provides the contact 250, which is a monolithic structure, for connecting the memory array to other elements, and thus the missed contact may be avoided.

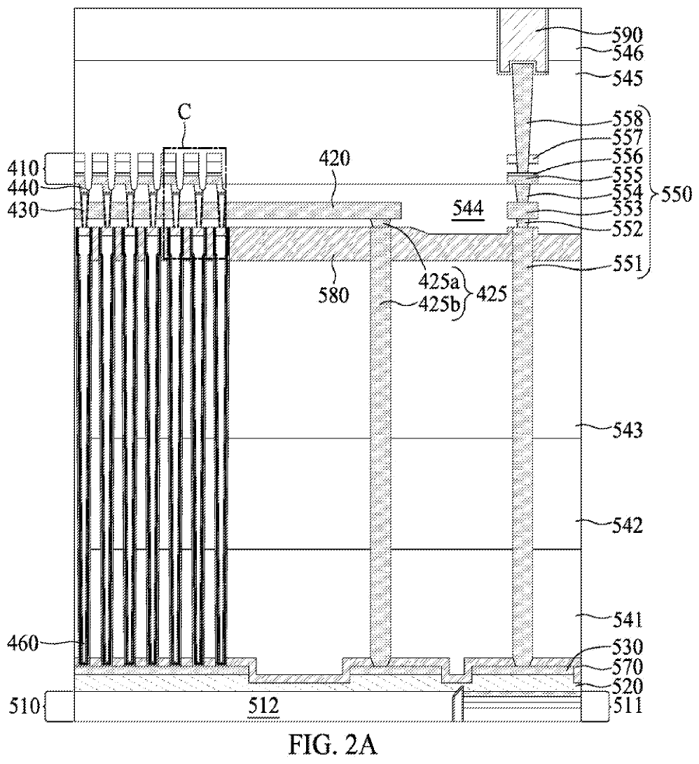

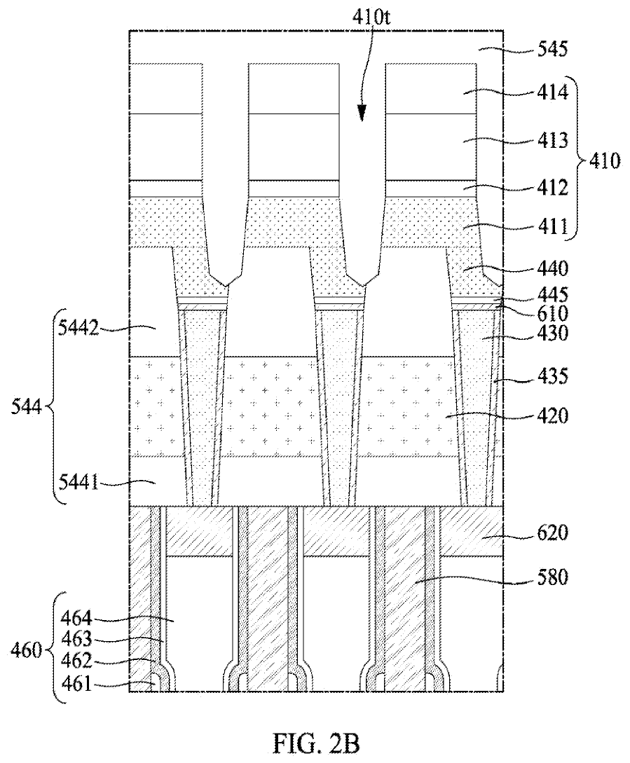

FIG. 2A is a cross-sectional view of a semiconductor device 2, in accordance with some embodiments of the present disclosure. In some embodiments, the semiconductor device 2 may include a capacitor that is formed prior to formation of other components.

The semiconductor device 2 includes a substrate 510, conductive layers 520 and 530, dielectric layers 541, 542, 543, 544, 545 and 546, bit lines 410, a word line 420, a word line contact 425, channel structures 430, landing pads 440, trench capacitors 460, a contact 550, and nitride layers 570 and 580.

Referring to FIG. 2A, the substrate 510 may be provided. The substrate 510 may be similar to the substrate 210, and thus a detailed description of the substrate 510 is omitted. In some embodiments, the substrate 510 may include a plurality of active areas (not shown). The active area may function as, for example, a channel for electrical connection.

The substrate 510 may include a conductive stack 511 for connecting to the active areas of the substrate 510. In some embodiments, the substrate 510 may include an isolation structure 512. In some embodiments, the plurality of active areas may be separated by the isolation structures 512.

The conductive layer 520 may be disposed on the substrate 510. The conductive layer 520 may be a patterned circuit layer. In some embodiments, the conductive layer 520 may be disposed on the isolation structure 512 and on the conductive stack 511 of the substrate 510. In some embodiments, the conductive layer 520 may be electrically connected to the active areas of the substrate 510 (not shown). The conductive layer 520 may be similar to the conductive layer 220, and thus a detailed description of the conductive layer 520 is omitted.

The conductive layer 530 may be disposed on the conductive layer 520. The conductive layer 530 may be similar to the conductive layer 230, and thus a detailed description of the conductive layer 530 is omitted.

The nitride layer 570 may be disposed on the conductive layer 530. In some embodiments, the nitride layer 570 may be conformal to the conductive layers 520 and 530. That is, the nitride layer 570 may cover top surfaces of the conductive layers 520 and 530. In some embodiments, a material of the nitride layer 570 may include silicon nitride (SiN).

In some embodiments, the dielectric layers 541, 542 and 543 may be disposed on the nitride layer 570. In some embodiments, the dielectric layer 541 may be disposed on the nitride layer 570. The dielectric layer 542 may be disposed on the dielectric layer 541. The dielectric layer 543 may be disposed on the dielectric layer 542.

The dielectric layers 541, 542 and 543 may be formed in different fabricating steps or in one step. In some embodiments, the dielectric layers 541, 542 and 543 may include a same material or similar materials. In another embodiment, the dielectric layers 541, 542 and 543 may include a same material with different concentrations. The dielectric layers 541, 542 and 543 may be similar to the dielectric layer 241, and thus detailed descriptions of the dielectric layers 541, 542 and 543 are omitted.

The nitride layer 580 is disposed on the dielectric layer 543. The nitride layer 580 may have an uneven top surface. For example, the nitride layer 580 may have a greater thickness on a left side (near an array of transistors) and a lesser thickness on a right side (a periphery region).

The trench capacitors 460 may be disposed on the substrate 510. The trench capacitors 460 may penetrate the nitride layer 580, the dielectric layers 541, 542 and 543, and the nitride layer 570. In some embodiments, the trench capacitors 460 may contact the conductive layer 530.

Details of the trench capacitors 460 are discussed below in view of FIG. 2A and FIG. 2B. FIG. 2B is an enlarged perspective view of a region C in FIG. 2A.

Referring to FIG. 2B, the trench capacitor 460 may include a multilayered stack (including conductive layers 461 and 463 and a dielectric layer 462) and a contact material 464. During fabrication of the trench capacitors 460, the nitride layer 580, the dielectric layers 541, 542 and 543, and the nitride layer 570 may be removed to form a plurality of trenches. The multilayered stack may be formed within the trenches, and the contact material 464 may then be deposited in the trench defined by the multilayered stack.

The conductive layers 461 and 463, the dielectric layer 462, and the contact material 464 may be similar to the conductive layers 161 and 163, the dielectric layer 162, and the contact material 164, respectively, and thus detailed descriptions of the conductive layers 461 and 463, the dielectric layer 462, and the contact material 464 are omitted.

In some embodiments, an ITO layer 620 may be disposed on the contact material 464. In some embodiments, the ITO layer 620 may be deposited in the trenches defined by the multilayered stack and in contact with the contact material 464. In some embodiments, a top surface of the ITO layer 620 may be coplanar with a top surface of the nitride layer 580.

Referring to FIG. 2A, the semiconductor device 2 may include the array of transistors (for example, the region C) disposed on the substrate 510. The array of transistors may include the bit lines 410, the landing pads 440, the channel structures 430, and the word line 420. Details of the array of transistors are discussed below in view of FIG. 2A and FIG. 2B.

A dielectric layer 5441 may be disposed on the trench capacitors 460. The dielectric layer 5441 may be similar to the dielectric layer 2411, and thus a detailed description of the dielectric layer 5441 is omitted.

The word line 420 may be disposed above the trench capacitors 460. In some embodiments, the word line 420 may be disposed on the dielectric layer 5441. The word line 420 may be similar to the word line 120, and thus a detailed description of the word line 420 is omitted.

A dielectric layer 5442 may be disposed on the word line 420. In some embodiments, the word line 420 may be disposed between the dielectric layers 5441 and 5442. The dielectric layer 5442 may be similar to the dielectric layer 2412, and thus a detailed description of the dielectric layer 5442 is omitted.

The channel structures 430 may be disposed on the trench capacitors 460. In some embodiments, the channel structures 430 may be disposed on the ITO layer 620. In some embodiments, the channel structures 430 may taper toward the trench capacitors 460. Each of the channel structures 430 may correspond to a respective one of the trench capacitors 460. The channel structures 430 may be separated from the word line 420 by a gate dielectric layer 435. The channel structures 430 may be similar to the channel structures 130, and thus a detailed description of the channel structures 430 is omitted. The gate dielectric layer 435 may be similar to the gate dielectric layer 135, and thus a detailed description of the gate dielectric layer 435 is omitted.

Referring to FIG. 2B, an ITO layer 610 may be disposed on the channel structures 430. In some embodiments, the ITO layer 610 may be thinner than the ITO layer 620.

In some embodiments, the landing pads 440 may be disposed on the ITO layer 610. The landing pads 440 may contact the ITO layer 610 (or the channel structures 430) through a titanium nitride layer 445.

In some embodiments, the landing pads 440 may taper toward the channel structures 430. That is, the landing pads 440 may have an upper width greater than a lower width. For example, a width of the titanium nitride layer 445 may be less than a width of the landing pads 440.

The bit lines 410 may be disposed on the landing pads 440. In some embodiments, the bit lines 410 may be connected to the channel structures 430 through the landing pads 440.

Referring to FIG. 2B, the bit lines 410 may include a multilayered stack (including conductive layers 411, 412 and 414, and a dielectric layer 413). The conductive layer 411 may be disposed on the dielectric layer 5442. The conductive layer 412 may be disposed on the conductive layer 411. In some embodiments, the dielectric layer 413 may be disposed on the conductive layer 412. The conductive layer 414 may be disposed on the dielectric layer 413.

The conductive layers 411, 412 and 414 may include metal, such as W, Cu, Ru, Ir, Ni, Os, Rh, Al, Mo, Co, alloys thereof, combinations thereof, or any metallic material with appropriate resistance and gap-filling capability. For example, the conductive layer 411 may include tungsten, the conductive layer 412 may include titanium nitride, and the conductive layer 414 may include copper. In some embodiments, the dielectric layer 413 may include a material similar to that of the dielectric layer 544.

After the multilayered stack of the bit line 410 is formed, a removal operation may be conducted, such that a plurality of openings 410t may be formed. The openings 410t may separate each bit line 410. In some embodiments, the formation of the openings 410t may include removing a portion of the landing pads 440, such that the landing pads 440 may be separated from the bit lines 410.

The dielectric layer 545 may be disposed on the bit lines 410 and deposited in the openings 410t. In some embodiments, the dielectric layer 545 may include a material similar to that of the dielectric layer 413.

In some embodiments, a distance between the landing pads 440 and an adjacent conductive layer 411 of the bit lines 410 may be small, and thus a short circuit may occur between the landing pad 440 and the adjacent bit line 410. Accordingly, the present disclosure shown in FIG. 1A may avoid such problem.

Referring back to FIG. 2A, the word line 420 may extend outside of the array of the transistors. In some embodiments, the semiconductor device 2 may include the word line contact 425 disposed between the word line 420 and the conductive layer 530. In some embodiments, the word line contact 425 may include two portions 425a and 425b.

The portion 425b of the word line contact 425 may penetrate the nitride layer 580, the dielectric layers 541, 542 and 543, and the nitride layer 570. In some embodiments, the portion 425b may be disposed on the conductive layer 530.

The portion 425a of the word line contact 425 may be disposed in the dielectric layer 544 and may be disposed on the portion 425b. Accordingly, the word line contact 425 may connect the word line 420 to the conductive layer 530. The word line contact 425 may be spaced apart from the channel structures 430.

Referring to FIG. 2A, the contact 550 may be disposed on and electrically connected to the conductive layer 530. In some embodiments, the contact 550 may penetrate the dielectric layers 541, 542, 543, 544 and 545, and the nitride layers 570 and 580. The contact 550 is spaced apart from the channel structures 430.

In some embodiments, the contact 550 may include a stack structure. The contact 550 may include pillars 551, 552, 554 and 558, and stages 553, 555, 556 and 557.

The pillar 551 may penetrate the nitride layer 580, the dielectric layers 541, 542 and 543, and the nitride layer 570. In some embodiments, the pillar 551 may be disposed on the conductive layer 530. In some embodiments, the pillar 551 may be formed in a same process as a formation of the portion 425b of the word line contact 425.

The pillar 552 may be disposed on the pillar 551. A size of the pillar 552 may be less than that of the pillar 551. For example, a diameter of the pillar 552 may be less than that of the pillar 551. In some embodiments, the pillar 552 may be formed in a same process as a formation of the portion 425a of the word line contact 425.

The stage 553 may be disposed on the pillar 552. In some embodiments, the stage 553 may be disposed within the dielectric layer 544. The stage 553 may be horizontally aligned with the word line 420. In some embodiments, the stage 553 may be formed in a same process as a formation of the word line 420.

The pillar 554 may be disposed on the stage 553. In some embodiments, the pillar 554 may be disposed within the dielectric layer 544. The pillar 554 may have a top surface aligned with a top surface of the landing pads 440.

The stage 555 may be disposed on the pillar 554. In some embodiments, the stage 555 may be disposed within the dielectric layer 545. The stage 555 may be horizontally aligned with the conductive layer 411 of the bit line 410. In some embodiments, the stage 555 may be formed in a same process as a formation of the conductive layer 411 of the bit line 410.

The stage 556 may be disposed on the stage 555. In some embodiments, the stage 556 may be disposed within the dielectric layer 545. The stage 556 may be horizontally aligned with the conductive layer 412 of the bit line 410. In some embodiments, the stage 556 may be formed in a same process as a formation of the conductive layer 412 of the bit line 410.

The stage 557 may be disposed on the stage 556. In some embodiments, the stage 557 may be disposed within the dielectric layer 545. The stage 557 may be horizontally aligned with the conductive layer 414 of the bit line 410. In some embodiments, the stage 557 may be formed in a same process as a formation of the conductive layer 414 of the bit line 410.

The pillar 558 may penetrate the stages 556 and 557, and may be disposed on the stage 555. The pillar 558 may be connected to the conductive layer 530 through the stage 555, the pillar 554, the stage 553, and the pillars 552 and 551.

An upper conductive layer 590 (referred to as the M1 layer) may be disposed within the dielectric layer 546. The upper conductive layer 590 may be disposed on the pillar 558 of the contact 550. A bottom surface of the upper conductive layer 590 may include a recess for accommodating the pillar 558. In other words, the pillar 558 may be partially covered by the upper conductive layer 590.

In some embodiments, the contact 550 may electrically connect the conductive layer 520 to the upper conductive layer 590. The upper conductive layer 590 may provide an electrical connection to other elements (for example, external elements). In some embodiments, the word line 420 may be electrically connected to the upper conductive layer 590 through the word line contact 425, the conductive layers 520 and 530, and the contact 550.

FIGS. 3A, 3B, 3C, 3D, 3E, 3F, 3G and 3H illustrate one or more operations of a method for fabricating a semiconductor device, in accordance with some embodiments of the present disclosure.

Referring to FIG. 3A, a substrate 210 is provided, and a conductive layer 220 may be formed on the substrate 210. In some embodiments, the substrate 210 may be at a wafer level or a panel level. The substrate 210 may include active areas 211 and an isolation structure 212 disposed within the active areas 211. In some embodiments, the active areas 211 may be separated by the isolation structures 212. In some embodiments, the conductive layer 220 may be disposed on and connected to the active areas 211 of the substrate 210. The conductive layer 220 may be a patterned circuit layer.

Referring to FIG. 3B, a dielectric layer 240a may be formed on the substrate 210, and a conductive layer 230 may be formed on and electrically connected to the conductive layer 220. The conductive layer 230 may include bit line conductive segments 231 and word line conductive segments 232. In some embodiments, the bit line conductive segments 231 may be substantially perpendicular to the word line conductive segments 232.

Referring to FIG. 3C, a plurality of bit line contacts 115 are formed on the bit line conductive segments 231. In some embodiments, each of the bit line conductive segments 231 may have one or more of the bit line contacts 115 disposed thereon. In some embodiments, the bit line contact 115 may be similar to the word line 125 described above.

Referring to FIG. 3D, a plurality of bit lines 110 are formed on the substrate 210; a plurality of lower landing pads 140 are formed on the bit lines 110; and an indium tin oxide (ITO) layer 320 is formed on a respective one of the lower landing pads 140. In some embodiments, the bit lines 110 are connected to the bit line conductive segments 231 through the bit line contacts 115. The bit lines 110 may extend along the Y-axis. In some embodiments, each of the bit lines 110 may include several of the lower landing pads 140 disposed thereon. As shown in FIG. 1C, each lower landing pad 140 includes a half portion covering the bit line 110.

Referring to FIG. 3E, a plurality of word line contacts 125 are formed on the word line conductive segments 232. In some embodiments, each of the word line conductive segments 232 may have one or more word line contacts 125 disposed thereon.

Referring to FIG. 3F, a plurality of word lines 120 are formed above the bit lines 110, a plurality of channel structures 130 are formed on the bit lines 110, and an indium tin oxide (ITO) layer 310 is formed on a respective one of the channel structures 130. In some embodiments, the word lines 120 are connected to the word line conductive segments 232 through the word line contacts 125. The word lines 120 may extend along the X-axis. In some embodiments, each of the word lines 120 may be penetrated by several of the channel structures 130. The channel structures 130 may be formed on the lower landing pads 140. In some embodiments, each channel structure 130 may correspond to one of the lower landing pads 140. In some embodiments, the channel structure 130 may have a gate dielectric layer 135 (not shown) formed between the word line 120 and the channel structure 130.

Referring to FIG. 3G, a plurality of upper landing pads 150 are formed on the channel structures 130. In some embodiments, the upper landing pads 150 may be connected to the channel structure 130 through the ITO layer 310.

Referring to FIG. 3H, a plurality of trench capacitors 160 are formed on the channel structures 130, a contact layer 164a and a conductive layer 180 are formed on the trench capacitors 160, and a dielectric layer 240 is formed on the dielectric layer 240a. In some embodiments, one of the trench capacitors 160 may correspond to a respective one of the channel structures 130. The dielectric layer 240 may cover elements above the dielectric layer 240a, for example, the channel structures 130, the trench capacitors 160, the contact layer 164a, and the conductive layer 180. In some embodiments, the dielectric layers 240a and 240 may be formed in several steps (such as steps used to form the dielectric layers 241, 242, 243, 244, 245, 246, 247 and 248 shown in FIG. 1A). As a result, a semiconductor device 1 as described and illustrated with reference to FIG. 1A is formed.

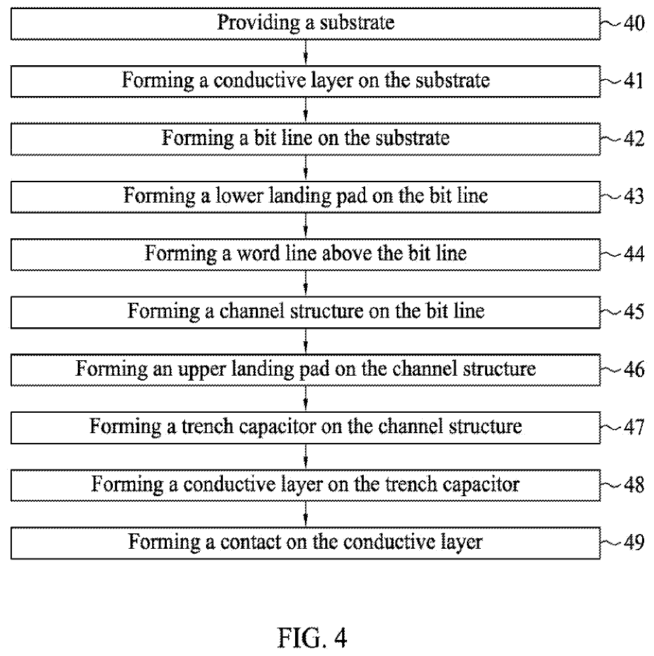

FIG. 4 is a flowchart of a method for fabricating a semiconductor device, in accordance with some embodiments of the present disclosure. In some embodiments, the method may be conducted to manufacture the semiconductor device 1 in FIG. 1A.

In operation 40, a substrate is provided. For example, the substrate 210 of FIG. 1A may be provided in operation 40.

In operation 41, a conductive layer (for example, the conductive layers 220 and/or 230) is formed on the substrate 210.

In operation 42, a bit line 110 is formed on the substrate 210. The bit line 110 extends along a first direction (Y-axis). In some embodiments, the conductive layers 220 and 230 may be disposed between the substrate 210 and the bit line 110.

In operation 43, a lower landing pad is formed on the bit line. For example, referring to FIG. 1A, a lower landing pad 140 is formed on the bit line 110 in operation 43.

In operation 44, a word line 120 is formed above the bit line 110. The word line 120 extends along a second direction (X-axis) perpendicular to the first direction. The word line 120 is formed on a first dielectric layer 2411. That is, the first dielectric layer 2411 is formed between the bit line 110 and the word line 120. In some embodiments, a second dielectric layer 2412 is formed on the word line 120. In other words, the first dielectric layers 2411 and 2412 may be formed on opposite sides of the word line 120.

In operation 45, a channel structure 130 is formed on the bit line 110. The channel structure 130 penetrates the word line 120 and is formed on the lower landing pad 140. That is, the lower landing pad 140 is disposed between the channel structure 130 and the bit line 110.

In some embodiments, forming the channel structure 130 includes forming an opening penetrating the first dielectric layer 2411, the word line 120, and the second dielectric layer 2412. After the opening is formed, a gate dielectric layer 135 may be formed within the opening, and the channel structure 130 may then be formed within the opening defined by the gate dielectric layer 135. In some embodiments, the gate dielectric layer 135 is formed between the word line 120 and the channel structure 130.

In operation 46, an upper landing pad 150 is formed on the channel structure 130. That is, the channel structure 130 is between the upper landing pad 150 and the lower landing pad 140.

In operation 47, a trench capacitor 160 is formed on the channel structure 130. In some embodiments, the trench capacitor 160 is disposed on the upper landing pad 150. That is, the upper landing pad 150 is disposed between the trench capacitor 160 and the channel structure 130.

In operation 48, a conductive layer is formed on the trench capacitor. For example, referring to FIG. 1A, a conductive layer 180 is formed on the trench capacitor 160 in operation 48.

In operation 49, a contact 250 is formed on the conductive layer (for example, the conductive layers 220 and/or 230). The contact 250 is spaced apart from the channel structure 130.

One aspect of the present disclosure provides a semiconductor device. The semiconductor device includes a substrate; a first bit line disposed on the substrate and extending along a first direction; a first word line disposed on the first bit line and extending along a second direction perpendicular to the first direction; a channel structure disposed on the first bit line and penetrating the first word line; a first dielectric layer disposed over the first bit line and a second dielectric layer disposed over the first word line; and a trench capacitor disposed on the channel structure. The channel structure is separated from the first word line by a gate dielectric layer. The second dielectric layer comprises a first air gap structure.

Another aspect of the present disclosure provides a semiconductor device. The semiconductor device includes a substrate; a channel structure disposed on the substrate; a first word line disposed on the substrate and surrounding the channel structure; a dielectric layer disposed over the substrate; and a trench capacitor disposed on the channel structure, opposite to the substrate. The trench capacitor comprises a first conductive layer, a second conductive layer, a first dielectric layer and a second dielectric layer.

Another aspect of the present disclosure provides a method for fabricating a semiconductor device. The method includes providing a substrate; forming a first bit line on the substrate, wherein the first bit line extends along a first direction; forming a first word line above the first bit line, wherein the first word line extends along a second direction perpendicular to the first direction; forming a channel structure on the first bit line, wherein the channel structure penetrates the first word line; forming a dielectric layer over the substrate; and forming a trench capacitor on the channel structure.

The embodiments of the present disclosure provide a semiconductor device with the capacitor formed last, thereby differentiating process and structure of the present disclosure from those of the prior art. For example, in the prior art, a contact connecting a memory array to other elements is manufactured by stacking several contacts and stages, while the present disclosure provides a monolithic contact connecting to the memory array, whereby misaligned (failed) contacts may be avoided. Furthermore, as a word line of the present disclosure is disposed near lower conductive layers on a substrate, a resistance of connection may be reduced due to a shortened electrical path (resulting from a shorter word line contact).

Regarding potential failure of a channel structure, in some embodiments, an etching process for fabricating the channel structure may fail to create a channel of sufficient depth. In such case, a bottom surface of the channel structure may contact the word line, such that the channel structure and the word line are short-circuited. In the prior art, because a bit line is disposed on the channel structure, a short circuit may occur between the bit line and the word line through the failed channel structure, and thus other channel structures connected to the same bit line will fail as well. In contrast, the present disclosure provides a semiconductor device with the capacitor formed last (i.e., the capacitor is disposed on the channel structure). With such configuration, a short circuit may occur between the word line and the capacitor (instead of the bit line) through the failed channel structure, and thus only one memory cell (i.e., the memory cell containing the failed channel structure) is affected. Accordingly, manufacturing yield and performance of the semiconductor device may be improved.

Although the present disclosure and its advantages have been described in detail, it should be understood that various changes, substitutions and alterations may be made herein without departing from the spirit and scope of the disclosure as defined by the appended claims. For example, many of the processes discussed above may be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A method for fabricating a semiconductor device, comprising:
providing a substrate;
forming a first bit line on the substrate, wherein the first bit line extends along a first direction;
forming a first word line above the first bit line, wherein the first word line extends along a second direction perpendicular to the first direction;
forming a channel structure on the first bit line, wherein the channel structure penetrates the first word line;
forming a dielectric layer over the substrate; and
forming a trench capacitor on the channel structure.

2. The method of claim 1, wherein the formation of the trench capacitor comprises forming a first conductive layer within the trench capacitor, wherein the first conductive layer partially covers a sidewall of portion of the dielectric layer.

3. The method of claim 2, wherein the formation of the trench capacitor further comprises forming a first dielectric layer covering the dielectric layer and the first conductive layer.

4. The method of claim 3, wherein the formation of the trench capacitor further comprises forming a second dielectric layer over the dielectric layer, wherein the second dielectric layer is disposed on a trench corner of the trenches and partially covers a top surface and a sidewall of the dielectric layer.

5. The method of claim 4, wherein the formation of the trench capacitor further comprises forming a second conductive layer over the dielectric layer, wherein the second conductive layer covers the first conductive layer, the first dielectric layer and the second dielectric layer.

6. The method of claim 5, wherein the first conductive layer and the second conductive layer are made of a same material.

7. The method of claim 5, wherein the first dielectric layer and the second dielectric layer are made of a same material.

8. The method of claim 6, wherein the same material is titanium nitride (TiN).

9. The method of claim 7, wherein the same material is zirconium oxide (ZrO₂), titanium oxide (TiO₂), or a combination thereof.
